(19) United States
(12) Patent Application Publication
(10) Pub. No.: US 2014/0174798 A1
(43) Pub. Date: Jun. 26, 2014

(54) METAL CORE SUBSTRATE AND METHOD OF MANUFACTURING THE SAME

(71) Applicant: Samsung Electro-Mechanics Co., Ltd.,, Suwon (KR)

(72) Inventors: Jae Hoon CHOI, Yongin (KR); Jong Kuk HONG, Suwon (KR)

(73) Assignee: Samsung Electro-Mechanics Co., Ltd.,, Suwon (KR)

(21) Appl. No.: 14/103,173

(22) Filed: Dec. 11, 2013

(30) Foreign Application Priority Data
Dec. 20, 2012 (KR) 10-2012-0149563

(51) Int. Cl. H05K 1/05; H05K 3/00

(52) U.S. Cl. CPC H05K 1/05; H05K 3/00
USPC 174/255; 156/60; 216/20; 156/268

(57) ABSTRACT

Disclosed herein are a metal core substrate and a method of manufacturing the same. The method of manufacturing a metal core substrate includes: forming a metal layer into which connection bridges are inserted; laminating an insulating layer and a copper foil on an upper surface and a lower surface of the metal layer en bloc; and removing the connection bridges.

### CROSS REFERENCE(S) TO RELATED APPLICATIONS

This application claims the foreign priority benefit under 35 U.S.C. Section 119 of Korean Application No. 10-2012-0149563, entitled “Metal Core Substrate and Method of Manufacturing the Same” filed on Dec. 20, 2012, which is hereby incorporated by reference in its entirety into this application.

### BACKGROUND OF THE INVENTION

1. Technical Field

The present invention relates to a metal core substrate and a method of manufacturing the same.

2. Description of the Related Art

As electronic components become smaller, denser and thinner, researches to develop a semiconductor package substrate which is thin but highly functional are also being actively conducted. As the recent chips have higher performance and faster operating speed, heat generated by the chips becomes a serious problem. Accordingly, it is common to manufacture a metal core substrate by inserting metal such as copper (Cu), aluminum (Al) and Invar which have good thermal conductivity. Further, since the chips are becoming thinner and thinner, it is also required to reduce the thickness of the core layer (copper-clad laminate or CCL) used in a printed circuit board to 0.02 T (=20 μm) or less.

Typically, a substrate having a metal inserted thereinto is manufactured by attaching an insulator and the metal through carrier or the first lamination, forming a circuit on the metal layer, and then performing the second lamination. In this case, however, unbalanced stress may cause warpage of the substrate. Accordingly, a roll-to-roll technique or a reel-to-reel technique is considered to configure the core layer with one collective unit, instead of cell units.

When only the metal core layer is loaded solely, however, it may not be possible to design etching lines per unit. Further, in sawing the substrate into units after the chips are mounted, metal may be exposed through sides so that a burr occurs, to cause a short-circuit.

In addition, when the core layer thinner than 0.02 T is loaded, the insulated layer is so thin that it may be broken during the processes.

### RELATED ART DOCUMENT

### Patent Document

(Patent Document 1) Korean Patent Laid-open Publication No. 2011-0059098

### SUMMARY OF THE INVENTION

An object of the present invention is to provide a metal core substrate and a method of manufacturing the same in which connection bridges between units are inserted when a circuit is formed on a metal core layer so as to connect the metal core layer so that a metal core layer can be configured with one collective unit instead of cell units, and the connection bridges are removed after lamination so that metal is less likely to be exposed through side surfaces even after the substrate is sawed into individual units of a final product.

Another object of the present invention is to provide a metal core substrate and a method of manufacturing the same in which a laminating process is performed only one time so as to reduce the process time by way of realizing an en bloc lamination by configuring the metal core layer with one collective unit instead of cell units, rather than sequential lamination that causes unbalanced stress to thereby cause warpage of the substrate.

Other objects of the present invention will be apparent from the following detailed description.

According to an exemplary embodiment of the present invention, there is provided a method of manufacturing a metal core substrate, including: forming a metal layer into which connection bridges are inserted; laminating an insulating layer and a copper foil on an upper surface and a lower surface of the metal layer en bloc; and removing the connection bridges.

The forming of the metal layer may include: preparing the metal layer; applying dry films on the upper and lower surface of the metal layer; performing exposure so that a circuit with etching design into which the connection bridges are inserted is formed on the dry film on the upper surface; and performing etching along the circuit.

The etching design may be for an etching line to distinguish among at least one of panels, strips, and units.

The removing of the connection bridges may include removing the connection bridges using a computer numerical control (CNC) drilling.

A metal exposed after the connection bridges is removed by the CNC drilling may be protected by a photo solder resist during later processes for manufacturing a three-layer metal core substrate.

A portion from which the connection bridges are removed by the CNC drilling may be filled with resin so that no metal is exposed during later processes for manufacturing a five-layer or higher metal core substrate.

According to another exemplary embodiment of the present invention, there is provided a metal core substrate manufactured by the method as described above.

These and other aspects, features and advantages will become apparent from the accompanying claims and the detailed descriptions.

### BRIEF DESCRIPTION OF THE DRAWINGS

FIG. 1 is a flowchart illustrating a method of manufacturing a metal core substrate according to an exemplary embodiment of the present disclosure;

FIGS. 2A to 2E are views illustrating a process of manufacturing a metal core substrate according to an exemplary embodiment of the present disclosure;

FIG. 3 is a set of views illustrating etching designs for distinguishing among strips and among units, into which connection bridges according to an exemplary embodiment of the present disclosure are inserted;

FIG. 4 is a view illustrating a process of removing connection bridges among units by drilling; and

FIGS. 5A and 5B are views for comparing a contracted substrate according to the related art with a contracted substrate according to the method of manufacturing a metal core substrate according to the exemplary embodiment of the present invention.

### DESCRIPTION OF THE PREFERRED EMBODIMENTS

Various modification may be made to the present invention and different exemplary embodiments of the present invention are conceivable. By way of illustration, specific exemplary embodiments will be depicted in the accompanying drawings and be described in detail in the specification. However, it is to be understood that the present invention is not limited to the specific exemplary embodiments, but includes all modifications, equivalents, and substitutions included in the spirit and the scope of the present invention. Further, in describing the present invention, descriptions on well-known features may be omitted in order not to obscure the gist of the present invention.

In the specification, the terms “first,” “second,” and so on are used to distinguish between similar elements and not necessarily for describing a sequential or chronological order. Terms used in the present specification are used only for describing specific exemplary embodiments of the present invention rather than limiting the present invention. Singular forms used herein are intended to include plural forms unless explicitly indicated otherwise. In the specification, it is to be noted that the terms “comprising” or “including” and the like are not to be construed as necessarily including all of the several features, numbers, steps, operations, components or combinations thereof described in the specification. Rather, some of the several features, numbers, steps, operations, components or combinations thereof may not be included or additional several features, numbers, steps, operations, components or combinations thereof are construed as being further included.

In the following detailed description, exemplary embodiments of the present disclosure will be described in detail with reference to the accompanying drawings. Throughout the drawings, like elements will be denoted by the same reference numerals and descriptions thereof will be omitted.

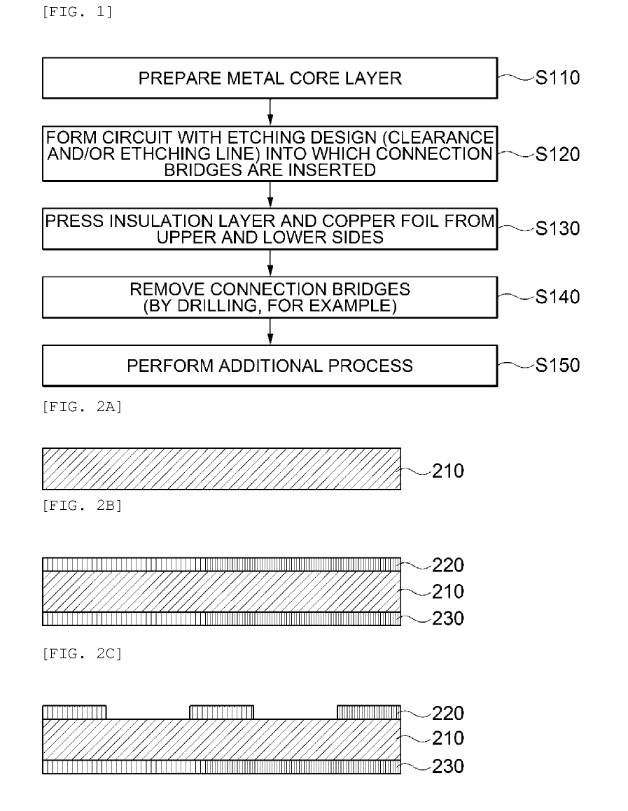

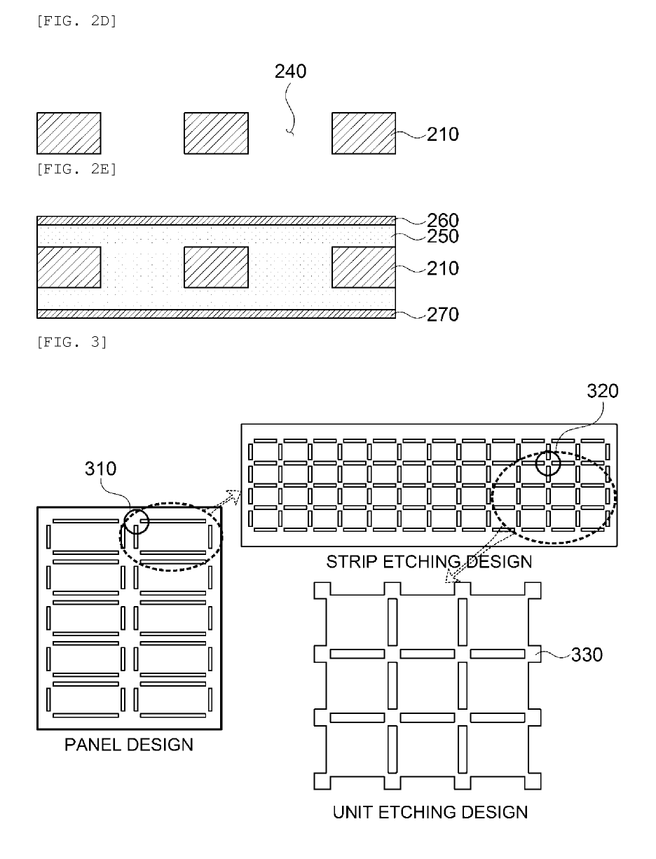

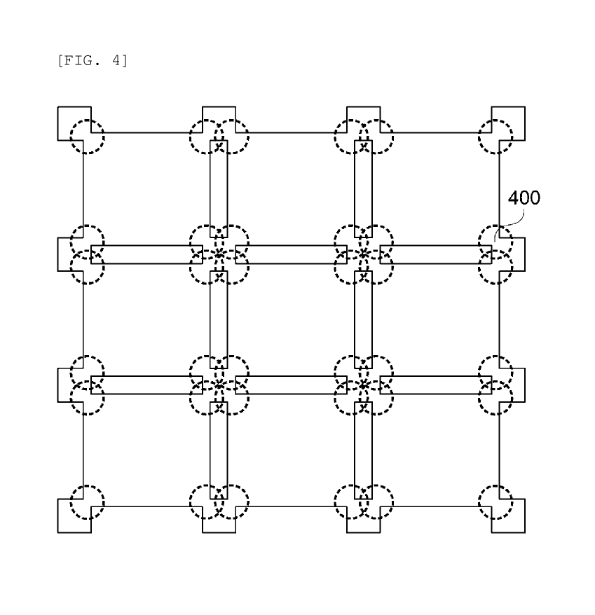

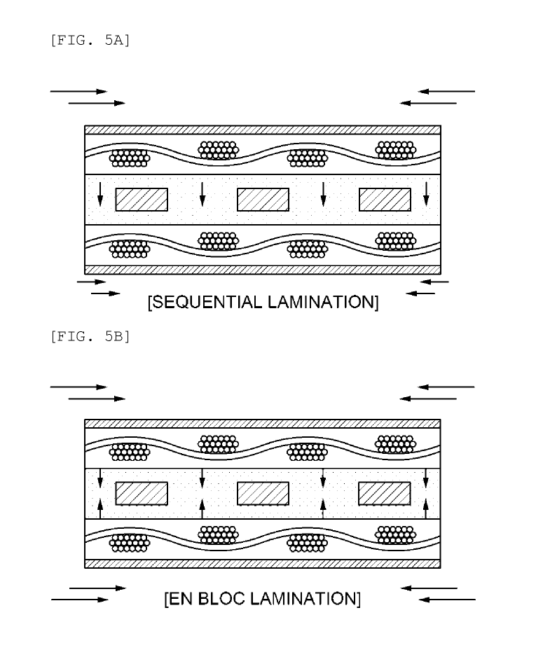

FIG. 1 is a flowchart illustrating a method of manufacturing a metal core substrate according to an exemplary embodiment of the present disclosure; FIGS. 2A to 2E are views illustrating a process of manufacturing a metal core substrate according to an exemplary embodiment of the present disclosure; FIG. 3 is a set of views illustrating an etching design for distinguishing among strips and units into which connection bridges according to an exemplary embodiment of the present disclosure are inserted; FIG. 4 is a view illustrating a process of removing connection bridges among units by drilling; and FIGS. 5A and 5B are views for comparing a contracted substrate according to the related art with a contracted substrate according to the method of manufacturing a metal core substrate according to the exemplary embodiment of the present invention.

In the method of manufacturing a metal core substrate according to the exemplary embodiment, laminating is performed en bloc by applying a roll-to-roll technique or a reel-to-reel technique to configure the core layer with one collective unit, instead of cell units. To this end, strips and units should not be completely separated but need to be connected by a bridge design. Accordingly, when connection bridge design is inserted in a circuit and thus the product is connected by the connection bridges, it is possible to configure the metal core layer with one collective unit instead of cell units and thus to realize en bloc lamination.

Referring to FIG. 1, the method of manufacturing a metal core substrate according to the exemplary embodiment will be described.

In operation 5110, a metal core layer 210 is prepared (see FIG. 2A). The metal core layer 210 serves as a core layer when the first lamination is completed later and may be, for example, made of copper or copper material such as copper-invar-copper (CIC). The CIC material is an Invar-foil with copper-plating on both sides and is used as a core layer.

In operation S120, a circuit with an etching design into which connection bridges are inserted is formed on the metal core layer 210 (see FIGS. 2B to 2D).

An example of a circuit with an etching design into which connection bridges are inserted is illustrated in FIG. 3. In panel designs, strip etching designs, unit etching designs and the like, connection bridges 310, 320 and 330 are inserted at every vertices of the panels, vertices of the strips and vertices of the units so as to connect the vertices to other panels, strips, and units or dummies and prevent the panels, strips, and units from being completely separated.

In the process of forming the circuit, dry films 220 and 230 are applied onto the upper and lower surfaces of the metal core layer 210 (see FIG. 2B) and patterns are formed by performing exposure (see FIG. 2C). Then, clearances 240 are formed because holes that have electrical connection through etching are not connected to the metal core layer 210. Thereafter, etching lines to distinguish between units and strips illustrated in FIG. 3 are formed and the dry films 220 and 230 are removed (see FIG. 2D).

In operation S130, after a black oxide or brown oxide treatment, an insulating layer 250 and copper foils 260 and 270 are pressed onto the upper and lower surfaces of the metal core layer 210 on which the circuit with an etching design with the connection bridges inserted into, thereby to manufacture a copper-clad laminate (CCL) having a three-layer substrate structure with the metal core 210 (see FIG. 2E). Here, laminating is performed en bloc on the both surfaces of the metal core layer 210 simultaneously. By forming the copper foil laminate having a three-layer substrate structure en bloc, it is possible to prevent warpage of the substrate which occurs in sequential lamination according to the related art.

In operation S140, after laminating is completed, the connection bridges are removed. The connection bridges may be removed by, for example, a CNC drilling the portions connected by the connection bridges.

FIG. 4 illustrates the removing of the connection bridges. A CNC drilling 400 may be performed one or more times on the portion where the connection bridges are inserted, so that they are separated into units, to obtain a finished product.

In operation S150, an additional process is performed by using the metal core substrate from which the connection bridges are removed. For an example, in the case of the metal core substrate having a three-layer substrate structure, the metal core portion exposed by the drilling in operation S140 may be protected by a photo solder resist (PSR).

For another example, In the case of the metal core substrate having a five-layer or higher substrate structure, an additional laminating process is performed in which the portions from which the connection bridges are removed (i.e., the drilled portions) are filled with resin, so that the metal core portion is not exposed.

FIGS. 5A and 5B are views for comparing a contracted substrate according to the related art with a contracted substrate according to the method of manufacturing a metal core substrate according to the exemplary embodiment of the present invention.

Referring to FIG. 5A, according to the related art, it can be seen that differences in contraction of the substrate are found in the uppermost layer and the lowermost layer since the layers are sequentially laminated, thereby causing warpage of the substrate.

In contrast, referring to FIG. 5B, according to the method of manufacturing a metal core substrate according to the exemplary embodiment, the uppermost layer and the lowermost layer are laminated en bloc and simultaneously so that they are contracted similarly, thereby preventing warpage of the substrate since forces applied to the upper side and to the lower side of the substrate are balanced.

Therefore, the problems previously occurring in the later processing, plating, and processing on a circuit with respect to operability are overcome and thus the production yield can be increased.

As set forth above, according to exemplary embodiments of the present invention, connection bridges between units are inserted when a circuit is formed on a metal core layer so as to connect the metal core layer so that the metal core layer can be configured with one collective unit and be subject to later processes, and the connection bridges are removed after lamination so that metal is less likely to be exposed through side surfaces even after the substrate is sawed into individual units of a final product.

Further, by realizing en bloc lamination by configuring the metal core layer with one collective units instead of cell units, rather than sequential lamination that causes unbalanced stress to thereby cause warpage of the substrate, a laminating process is performed only one time so as to save the process time.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A method of manufacturing a metal core substrate, comprising:
forming a metal layer into which connection bridges are inserted;
laminating an insulating layer and a copper foil on an upper surface and a lower surface of the metal layer en bloc; and
removing the connection bridges therefrom.

2. The method according to claim 1, wherein the forming of the metal layer includes:
preparing the metal layer;
applying dry films on the upper and lower surface of the metal layer;
performing exposure so that a circuit with an etching design into which the connection bridges are inserted is formed on the dry film on the upper surface; and
performing etching along the circuit.

3. The method according to claim 2, wherein the etching design includes an etching line to distinguish among at least one of panels, strips, and units.

4. The method according to claim 1, wherein the removing of the connection bridges includes removing the connection bridges using a computer numerical control (CNC) drilling.

5. The method according to claim 4, wherein a metal exposed after the connection bridges are removed by the CNC drilling is protected by a photo solder resist during later processes for manufacturing a three-layer metal core substrate.

6. The method according to claim 4, wherein a portion from which the connection bridges are removed by the CNC drilling is filled with resin so that no metal is exposed during later processes for manufacturing a five-layer or higher metal core substrate.

7. A metal core substrate manufactured by the method according to claim 1.

8. A metal core substrate manufactured by the method according to claim 2.

9. A metal core substrate manufactured by the method according to claim 3.

10. A metal core substrate manufactured by the method according to claim 4.

11. A metal core substrate manufactured by the method according to claim 5.

12. A metal core substrate manufactured by the method according to claim 6.
